(19) United States
(12) Patent Application Publication
(10) Pub. No.: US 2025/0154642 A1
(43) Pub. Date: May 15, 2025

(54) RELEASE STRUCTURE AND MANUFACTURING METHOD OF SUBSTRATE

(71) Applicant: AUO Corporation, Hsinchu City (TW)

(72) Inventor: Shu-Hui Chen, Hsinchu City (TW)

(73) Assignee: AUO Corporation, Hsinchu City (TW)

(21) Appl. No.: 18/822,281

(22) Filed: Sep. 2, 2024

(30) Foreign Application Priority Data
Nov. 14, 2023 (TW) 112143810

(51) Int. Cl. C23C 16/01; C23C 14/16; C23C 14/54; C23C 16/24; G02B 5/20

(52) U.S. Cl. CPC C23C 16/01; C23C 14/16; C23C 14/54; C23C 16/24; G02B 5/20

(57) ABSTRACT

The disclosure provides a release structure, which includes a first carrier, an amorphous silicon layer, a metal layer, a photoresist layer, and a buffer structure. The amorphous silicon layer is located on the first carrier. The metal layer is located on the amorphous silicon layer. The photoresist layer is located on the metal layer. The buffer structure is located on the photoresist layer.

### CROSS-REFERENCE TO RELATED APPLICATION

This application claims the priority benefit of Taiwan application serial no. 112143810, filed on Nov. 14, 2023. The entirety of the above-mentioned patent application is hereby incorporated by reference herein and made a part of this specification.

### BACKGROUND

### Technical Field

The disclosure relates to a release structure and a manufacturing method of a substrate.

### Description of Related Art

Since an organic material has advantages of light weight, softness, and easy processing, it is often used as a substrate for an electronic device. For example, when a flexible display device or a stretchable display device is manufactured, the organic material is often used as the substrate, and elements with various functions are formed on the substrate. Currently, an organic material layer is usually formed on a working carrier first, and then the organic material layer is peeled off from the working carrier to be used for various purposes. However, when the organic material layer is peeled off, a surface of the organic material layer is easily damaged. Therefore, there is an urgent need for a method that may solve the aforementioned issue.

### SUMMARY

The disclosure provides a release structure and a manufacturing method of a substrate, which may reduce damage to a photoresist layer during a laser peeling process.

At least one embodiment of the disclosure provides a manufacturing method of a substrate, including the following steps. An amorphous silicon layer is deposited on a first carrier using chemical vapor deposition. A precursor used in the chemical vapor deposition includes H2 gas and SiH4 gas. A flow rate of the H2 gas is 610 sccm to 2540 sccm, and a flow rate of the SiH4 gas is 270 sccm to 540 sccm. A metal layer is deposited on the amorphous silicon layer using physical vapor deposition. Power used in the physical vapor deposition is 1000 W to 3000 W, and surface roughness Ra of the metal layer is 0.4 nanometers to 0.75 nanometers. A photoresist layer is formed on the metal layer. A buffer structure is deposited on the photoresist layer. The photoresist layer and the buffer structure are taken from the metal layer using a laser peeling process. The photoresist layer is disposed on a second carrier. The photoresist layer is located between the second carrier and the buffer structure.

At least one embodiment of the disclosure provides a release structure, including a first carrier, an amorphous silicon layer, a metal layer, a photoresist layer, and a buffer structure. The amorphous silicon layer is located on the first carrier. The metal layer is located on the amorphous silicon layer, and surface roughness of the metal layer is 0.4 nanometers to 0.75 nanometers. The photoresist layer is located on the metal layer. The buffer structure is located on the photoresist layer.

### BRIEF DESCRIPTION OF THE DRAWINGS

FIGS. 1A to 1E are schematic cross-sectional views of a manufacturing method of a release structure according to an embodiment of the disclosure.

FIGS. 2A to 2C are schematic cross-sectional views of a manufacturing method of a substrate according to an embodiment of the disclosure.

FIG. 3 is a schematic cross-sectional view of a substrate according to another embodiment of the disclosure.

FIG. 4 is a schematic cross-sectional view of a release structure according to another embodiment of the disclosure.

### DETAILED DESCRIPTION OF DISCLOSED EMBODIMENTS

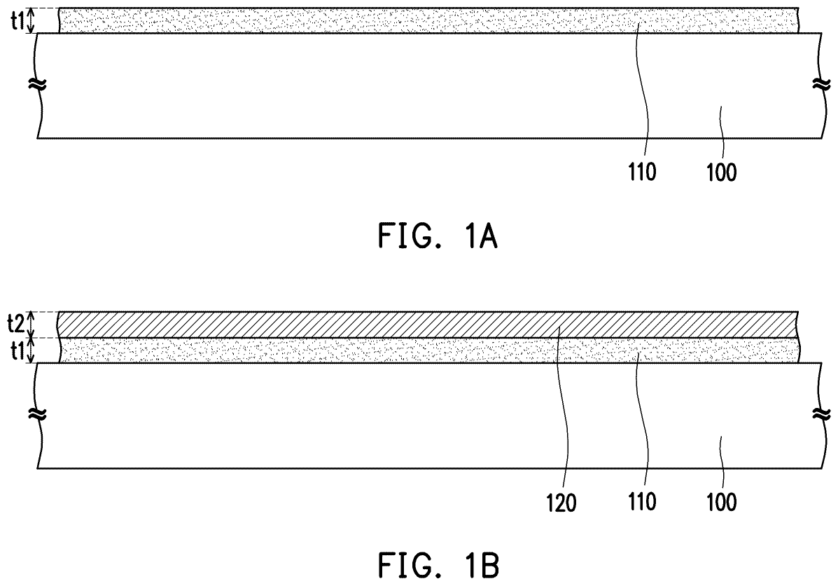

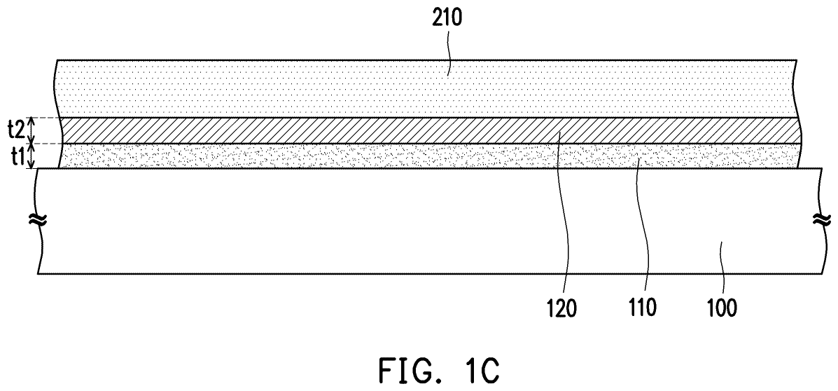

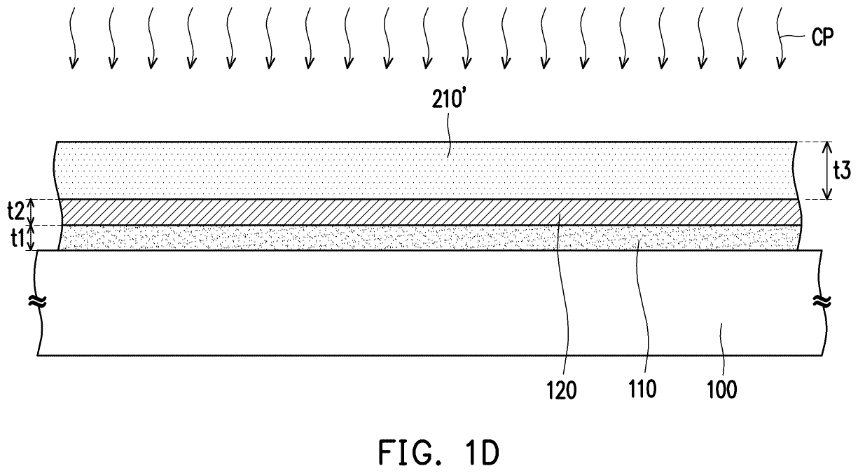

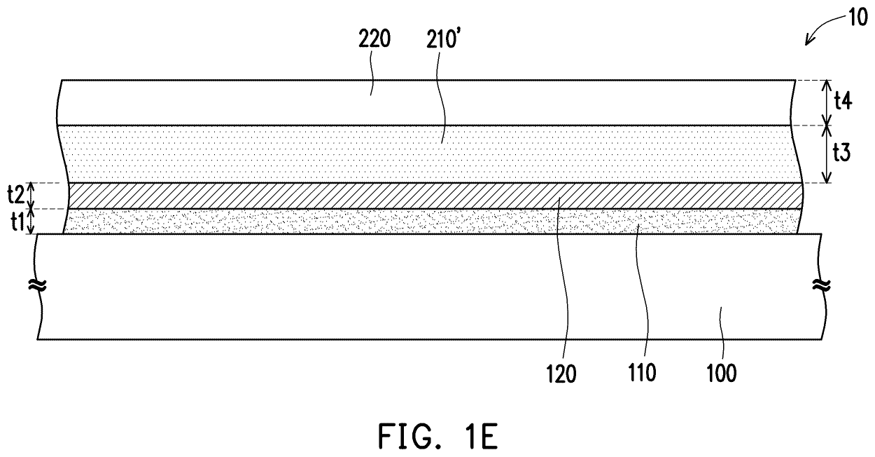

FIGS. 1A to 1E are schematic cross-sectional views of a manufacturing method of a release structure 10 according to an embodiment of the disclosure. Referring to FIG. 1A, an amorphous silicon layer 110 is deposited on a first carrier 100. In some embodiments, the first carrier 100 includes glass, quartz, wafers, or other suitable hard carriers. In some embodiments, the first carrier 100 is a transparent carrier.

A method of depositing the amorphous silicon layer 110 includes chemical vapor deposition, and a used precursor includes H₂ gas and SiH₄ gas. For example, the precursor including the H₂ gas and the SiH₄ gas is applied on the first carrier 100, and silicon is generated after decomposition of SiH₄ to be deposited on the first carrier 100, thereby obtaining the amorphous silicon layer 110. In some embodiments, the precursor used in the chemical vapor deposition does not include argon. In some embodiments, a flow rate of the H₂ gas is 610 sccm to 2540 sccm, and a flow rate of the SiH₄ gas is 270 sccm to 540 sccm, thereby obtaining the amorphous silicon layer 110 with low compactness. In some embodiments, the flow rate of the H₂ gas is 610 sccm, and the flow rate of the SiH₄ gas is 270 sccm. In some embodiments, a thickness t1 of the amorphous silicon layer 110 is 50 angstroms to 150 angstroms.

Referring to FIG. 1B, a metal layer 120 is deposited on the amorphous silicon layer 110 using physical vapor deposition. In this embodiment, power used in the physical vapor deposition is 1000 W to 3000 W, and the power of 2000 W is better. By controlling the power used in the physical vapor deposition, the metal layer 120 with lower surface roughness Ra may be obtained. In this embodiment, the surface roughness Ra of the metal layer 120 is 0.4 nm to 0.75 nm, and has low compactness. In some embodiments, a thickness t2 of the metal layer 120 is 50 angstroms to 150 angstroms. In some embodiments, a material of metal layer 120 includes molybdenum or aluminum. Due to existence of the amorphous silicon layer 110, an issue of peeling between the metal layer 120 and the first carrier 100 may be avoided. In some embodiments, the metal layer 120 may also be called a release layer.

The physical vapor deposition is performed using different power to obtain the metal layers (e.g., molybdenum) with different surface roughness Ra, and results are shown in Table 1.

TABLE 1

| Power used in physical vapor | Surface roughness Ra of metal |
|---|---|
| deposition | layer |
| 5000 W | 0.8164 nm |
| 3000 W | 0.7246 nm |
| 2000 W | 0.6885 nm |
| 1000 W | 0.5934 nm |

According to Table 1, when the power in the physical vapor deposition is higher, the surface roughness Ra of the metal layer 120 obtained is greater, which may increase a contact area between the metal layer 120 and a subsequently formed photoresist layer 210′ (referring to FIG. 1D), and require a laser with greater energy to perform peeling between the metal layer 120 and the photoresist layer 210′. Therefore, the power used when depositing the metal layer 120 is too high, which is not conducive to reducing laser energy required for a peeling process. However, if the power in the physical vapor deposition is too low, the required laser energy will peel off the amorphous silicon layer 110. Based on the above, the power used when depositing the metal layer 120 is preferably 1000 W to 3000 W.

Referring to FIG. 1C, a photoresist material layer 210 is formed on the metal layer 120. In some embodiments, a method of forming the photoresist material layer 210 includes spin coating or other suitable processes. In some embodiments, the photoresist material layer 210 includes a positive photoresist or a negative photoresist.

Referring to FIG. 1D, the photoresist material layer 210 is cured through a curing process CP, thereby forming the photoresist layer 210′ on the metal layer 120. In some embodiments, the curing process CP is, for example, an ultraviolet curing process or other suitable processes. In some embodiments, a patterning process is optionally performed on the photoresist material layer 210, and an unnecessary portion in the photoresist material layer 210 is removed through a development process. For example, the curing process CP includes exposing the photoresist material layer 210 using a photomask, and then removing the unnecessary portion in the photoresist material layer 210 using a developer. In some embodiments, a thickness t3 of the photoresist layer 210′ is 2000 nm to 2700 nm.

Referring to FIG. 1E, a buffer structure 220 is deposited on the photoresist layer 210′. In some embodiments, the photoresist layer 210′ includes organic materials, and the buffer structure 220 includes inorganic materials. In some embodiments, the buffer structure 220 includes silicon oxide, silicon nitride, silicon oxynitride, aluminum oxide, or other suitable materials or a combination of the foregoing materials. The buffer structure 220 has, for example, a single layer or a multi-layer structure. In some embodiments, a thickness t4 of the buffer structure 220 is 1000 angstroms to 2000 angstroms. In some embodiments, a method of depositing the buffer structure 220 includes a chemical vapor deposition process or other suitable processes.

So far, the release structure 10 has been roughly completed. In the release structure 10, the metal layer 120 is configured to be separated from the photoresist layer 210′ using a laser peeling process.

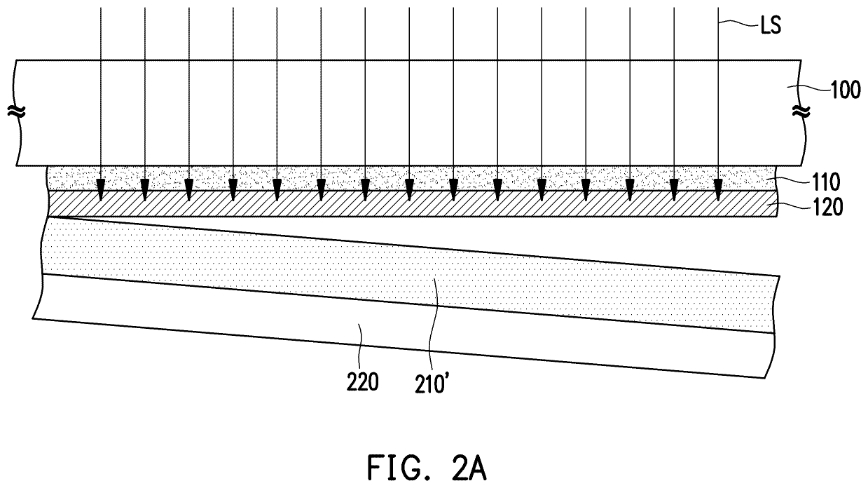

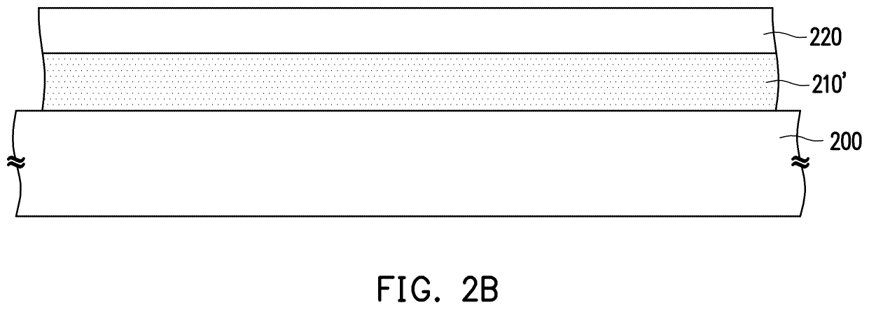

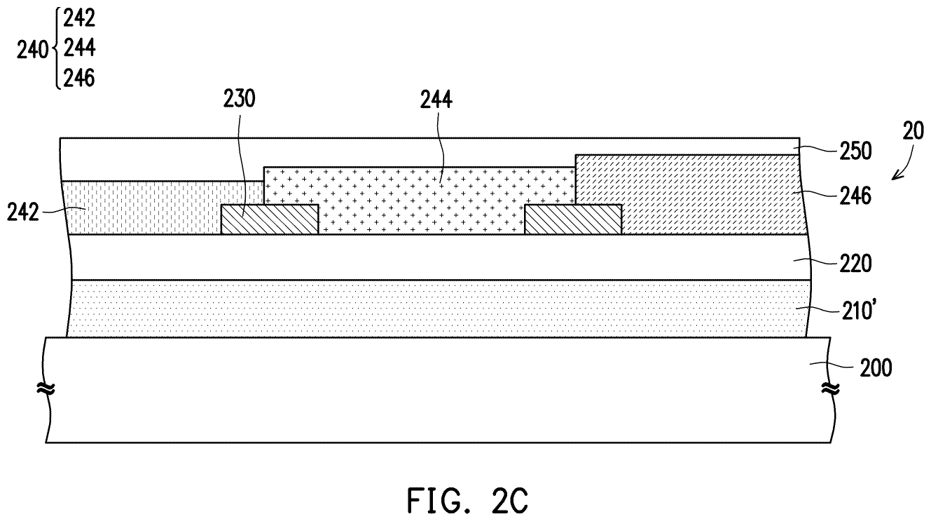

FIGS. 2A to 2C are schematic cross-sectional views of a manufacturing method of a substrate 20 according to an embodiment of the disclosure. Referring to FIG. 2A, the release structure 10 as shown in FIG. 1E is provided. Next, the photoresist layer 210′ and the buffer structure 220 are taken from the metal layer 120 using a laser peeling process LS. The metal layer 120 may absorb the laser energy to be separated from the photoresist layer 210′. In this embodiment, since the metal layer 120 has the low surface roughness Ra, only the laser with the lower energy is used to separate the photoresist layer 210′ from the metal layer 120, thereby preventing the photoresist layer 210′ from being damaged during the laser peeling process LS. In some embodiments, the laser energy used in the laser peeling process LS is less than 400 mJ/cm². For example, the energy used in the laser peeling process LS is 300 mJ/cm², 320 mJ/cm², 340 mJ/cm², 360 mJ/cm², or 380 mJ/cm².

In some embodiments, while the photoresist layer 210′ and the metal layer 120 are separated using the laser peeling process LS, other fixtures (not shown) are used to pick up the photoresist layer 210′ and the buffer structure 220.

Referring to FIG. 2B, the photoresist layer 210′ is disposed on a second carrier 200. The photoresist layer 210′ is located between the second carrier 200 and the buffer structure 220, and is in contact with the second carrier 200. In some embodiments, the second carrier 200 includes glass, quartz, wafers, or other suitable hard carriers.

In this embodiment, since a surface of the photoresist layer 210′ will not be significantly damaged after the foregoing laser peeling process, the photoresist layer 210′ may be better attached to the second carrier 200. In some embodiments, a release layer (not shown) is optionally formed on the second carrier 200, and the release layer helps to remove the second carrier 200 in subsequent processes.

Referring to FIG. 2C, a black matrix 230 is formed above the buffer structure 220. A color filter structure 240 is formed above the buffer structure 220. In some embodiments, the color filter structure 240 includes a first color filter element 242, a second color filter element 244, and a third color filter element 246. In some embodiments, the first color filter element 242, the second color filter element 244, and the third color filter element 246 include photoresist materials of different colors, such as green, red, and blue. The black matrix 230 is used to isolate filter elements of different colors.

Finally, a protective layer 250 is formed above the black matrix 230 and the color filter structure 240. In some embodiments, a material of the protective layer 250 includes silicon oxide, silicon nitride, silicon oxynitride, aluminum oxide, or other suitable materials. In some embodiments, a method of forming the protective layer 250 includes the chemical vapor deposition process or other suitable processes.

So far, the substrate 20 has been roughly completed. In some embodiments, the substrate 20 is, for example, a color filter element substrate, and is suitable for use in liquid crystal display devices, micro light-emitting diode display devices, organic light-emitting diode display devices, or other display devices. In some embodiments, the second carrier 200 is optionally removed. In some embodiments, a flexible substrate is obtained after the second carrier 200 is removed.

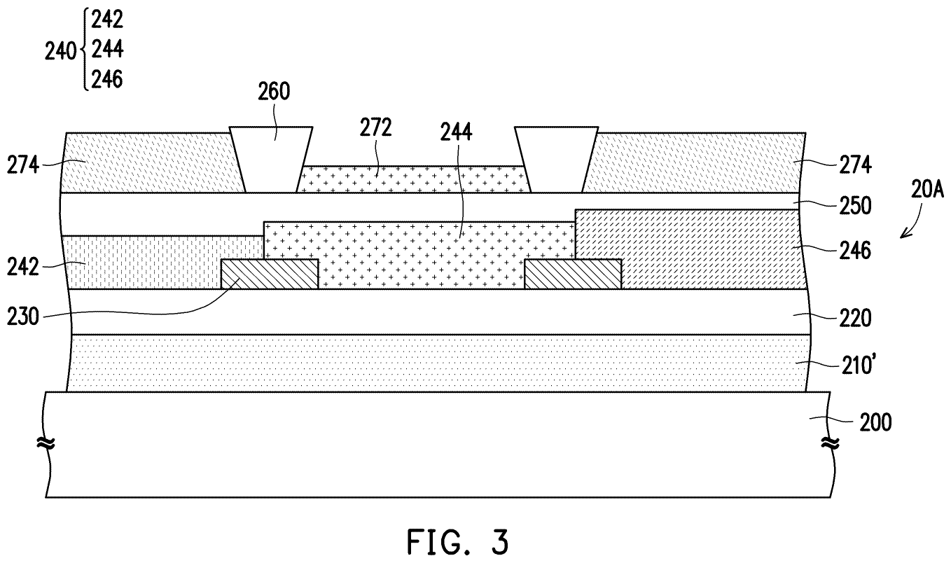

FIG. 3 is a schematic cross-sectional view of a substrate 20A according to another embodiment of the disclosure. It is noted that some of the reference numerals and descriptions in the embodiment of FIG. 2C will apply to the embodiment of FIG. 3. The same or similar reference numerals will represent the same or similar components and the descriptions of the same technical contents will be omitted. Reference may be made to the above embodiment for the omitted descriptions, which will not be repeated in the following.

Referring to FIG. 3, a retaining wall structure 260 is formed on the protective layer 250. In some embodiments, the retaining wall structure 260 includes organic materials and reflective particles distributed in the foregoing organic materials or other light-reflective microstructures. By enabling the retaining wall structure 260 to have light-reflective properties, light-emitting efficiency of the display device may be improved.

In some embodiments, the retaining wall structure 260 overlaps the black matrix 230 in a normal direction of a top surface of the second carrier 200.

A color conversion layer 272 is formed on the protective layer 250. In some embodiments, the color conversion layer 272 includes a photoluminescent material. For example, the color conversion layer 272 includes at least one of a quantum dot material, a fluorescent material, and a perovskite material.

In some embodiments, the color conversion layer 272 overlaps the second color filter element 244 in the normal direction of the top surface of the second carrier 200. The second color filter element 244 and the color conversion layer 272 include corresponding colors. For example, the color conversion layer 272 is used to receive blue light emitted by a blue light-emitting diode, and absorb the blue light and then emit red light. The second color filter element 244 is used to filter the blue light that directly passes through the color conversion layer 272 to prevent the blue light emitted by the blue light-emitting diode from directly passing through the second color filter element 244.

A light-transmitting layer 274 is formed on the protective layer 250. In some embodiments, the light-transmitting layer 274 overlaps the first color filter element 242 and the third color filter element 246 in the normal direction of the top surface of the second carrier 200.

So far, the substrate 20A has been roughly completed. In some embodiments, the substrate 20A is, for example, a color filter element substrate, and is suitable for use in the liquid crystal display devices, the micro light-emitting diode display devices, the organic light-emitting diode display devices, or other display devices. In some embodiments, the second carrier 200 is optionally removed. In some embodiments, the flexible substrate is obtained after the second carrier 200 is removed.

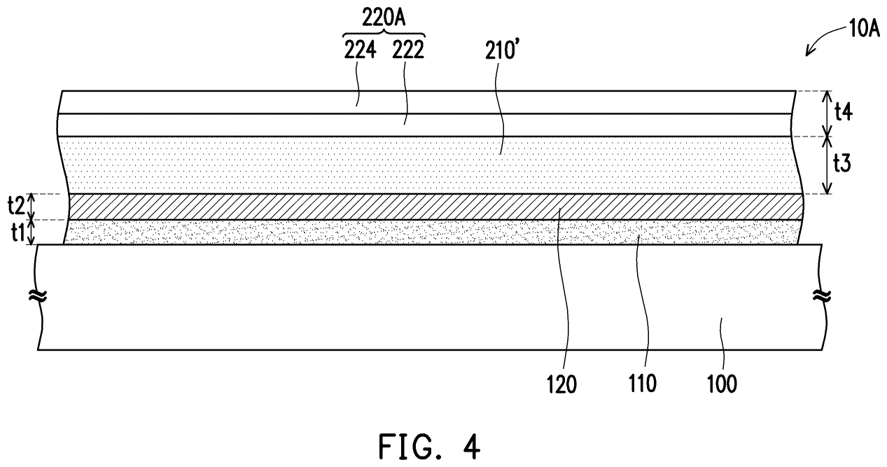

FIG. 4 is a schematic cross-sectional view of a release structure 10A according to another embodiment of the disclosure. It is noted that some of the reference numerals and descriptions in the embodiment of FIG. 1E will apply to the embodiment of FIG. 4. The same or similar reference numerals will represent the same or similar components and the descriptions of the same technical contents will be omitted. Reference may be made to the above embodiment for the omitted descriptions, which will not be repeated in the following.

The release structure 10A in FIG. 4 is similar to the release structure 10 in FIG. 1E. A main difference between the two is that a buffer structure 220A of the release structure 10A has a multi-layer structure. The buffer structure 220A includes a first layer 222 and a second layer 224. In some embodiments, one of the first layer 222 and the second layer 224 is a silicon oxide layer, and the other is a silicon nitride layer. In this embodiment, the buffer structure 220A has a dual-layer structure as an example, but the disclosure is not limited thereto. In other embodiments, the buffer structure 220A has a structure of more than three layers.

Based on the above, by adjusting the precursor used to form the amorphous silicon layer and the power in the physical vapor deposition used to form the metal layer, the metal layer with the low surface roughness Ra may be obtained, so that the photoresist layer located on the metal layer may be removed through the laser peeling process with the low energy, and the damage to the photoresist layer caused by the laser peeling process is reduced.

What is claimed is:

1. A manufacturing method of a substrate, comprising:
depositing an amorphous silicon layer on a first carrier using chemical vapor deposition, wherein a precursor used in the chemical vapor deposition comprises H₂ gas and SiH₄ gas, a flow rate of the H₂ gas is 610 sccm to 2540 sccm, and a flow rate of the SiH₄ gas is 270 sccm to 540 sccm;
depositing a metal layer on the amorphous silicon layer using physical vapor deposition, wherein power used in the physical vapor deposition is 1000 W to 3000 W, and surface roughness Ra of the metal layer is 0.4 nanometers to 0.75 nanometers;
forming a photoresist layer on the metal layer;
depositing a buffer structure on the photoresist layer;
taking the photoresist layer and the buffer structure from the metal layer using a laser peeling process; and
disposing the photoresist layer on a second carrier, wherein the photoresist layer is located between the second carrier and the buffer structure.

2. The manufacturing method of the substrate according to claim 1, wherein after disposing the photoresist layer on the second carrier, the method further comprises:
forming a black matrix above the buffer structure;
forming a color filter structure above the buffer structure;
forming a protective layer on the black matrix and the color filter structure;
forming a retaining wall structure above the protective layer; and
forming a color conversion layer above the protective layer.

3. The manufacturing method of the substrate according to claim 2, further comprising:
removing the second carrier.

4. The manufacturing method of the substrate according to claim 1, wherein laser energy used in the laser peeling process is less than 400 mJ/cm².

5. The manufacturing method of the substrate according to claim 1, wherein a method of forming the photoresist layer comprises:
forming a photoresist material layer on the metal layer, wherein a method of forming the photoresist material layer comprises spin coating; and
before depositing the buffer structure, curing the photoresist material layer to form the photoresist layer.

6. The manufacturing method of the substrate according to claim 1, wherein the precursor used in the chemical vapor deposition does not comprise argon.

7. A release structure, comprising:
a first carrier;
an amorphous silicon layer located on the first carrier;
a metal layer located on the amorphous silicon layer, wherein surface roughness of the metal layer is 0.4 nanometers to 0.75 nanometers;
a photoresist layer located on the metal layer; and
a buffer structure located on the photoresist layer.

8. The release structure according to claim 7, wherein a thickness of the amorphous silicon layer is 50 angstroms to 150 angstroms, a thickness of the metal layer is 50 angstroms to 150 angstroms, and a thickness of the buffer structure is 1000 angstroms to 2000 angstroms.

9. The release structure according to claim 7, wherein the buffer structure has a multi-layer structure.

10. The release structure according to claim 7, wherein the metal layer is configured to be separated from the photoresist layer after a laser peeling process with energy less than 400 mJ/cm².
